(19) United States
(12) Patent Application Publication
(10) Pub. No.: US 2026/0172017 A1
(43) Pub. Date: Jun. 18, 2026

(54) Offset Calibration Circuit and Method, Chip and Electronic Device

(71) Applicant: INNOGRIT TECHNOLOGIES CO., LTD., Shanghai (CN)

(72) Inventors: Xiuli XU, Shanghai (CN); Nannan YU, Shanghai (CN); Lei JIANG, Shanghai (CN); Yongxu WANG, Shanghai (CN)

(21) Appl. No.: 19/422,924

(22) Filed: Dec. 17, 2025

(30) Foreign Application Priority Data
Dec. 18, 2024 (CN) 202411866754.5

(51) Int. Cl. H03K 5/24; H03M 1/10

(52) U.S. Cl. CPC H03K 5/2481; H03M 1/1023

(57) ABSTRACT

The present disclosure relates to an offset calibration circuit and method, a chip and electronic device, the offset calibration circuit comprises a first switch and a second switch, a first terminal of the first switch is for receiving a reference level, a first terminal of the second switch is connected to a first input terminal of the comparator to receive a DC common-mode level, and a second terminal of the first switch, a second terminal of the second switch, and a second input terminal of the comparator are connected to each other. The offset calibration circuit of the embodiment of the present disclosure changes the switch connection mode of the input terminal of the comparator, and reduces the number of switches on the input signal line, so that the data signal (for example, a DC common-mode level) may be directly connected to an input terminal of a comparator.

### CROSS-REFERENCE TO RELATED APPLICATION

The present application is based upon and claims the benefit of a priority of Chinese Patent Application No. 202411866754.5, filed on Dec. 18, 2024, the entire contents of all of which are incorporated herein by reference.

### TECHNICAL FIELD

The present disclosure relates to the field of electronic circuit technologies, and in particular, to an offset calibration circuit and method, a chip, and an electronic device.

### BACKGROUND

In a high-speed single-ended receiver (RX), a single-ended high-speed data signal and a reference voltage enter a comparator, and then complete data information is output. The transmission rate, the bit error rate, the signal bandwidth, the signal offset, and the like are all closely related circuit design parameters. With the popularization of double data rate synchronous dynamic random access memory (DDR SDRAM) communication interface (IO) systems and flash (NAND) communication interface (IO) systems, the data transmission rate is getting faster and faster, and in order to increase the circuit bandwidth, the receiver will add various equalization techniques and increase the complexity of the circuit design, which inevitably increases the offset of the circuit and reduces the bit error rate of the circuit.

### SUMMARY

The present disclosure provides an offset calibration technical solution.

According to an aspect of the present disclosure, there is provided an offset calibration circuit for calibrating a comparator, the offset calibration circuit comprising a first switch and a second switch, a first terminal of the first switch is for receiving a reference level, a first terminal of the second switch is connected to a first input terminal of the comparator to receive a DC common-mode level, and a second terminal of the first switch, a second terminal of the second switch, and a second input terminal of the comparator are connected to each other.

In an embodiment, the DC common-mode level is from a transmit circuit, and the transmit circuit configures the DC common-mode level to be a same calibration level as the reference level; the first switch is turned off, and the second switch is turned on, so that the first input terminal and the second input terminal of the comparator receive the calibration level; and the comparator performs calibration according to the calibration level until the comparator outputs a jump signal, where the jump signal is for indicating that offset calibration for the comparator is completed.

In an embodiment, the calibrating the comparator according to the calibration level until the comparator outputs the jump signal comprises: in a case that the comparator outputs a steady-state signal, the comparator performs calibration according to the calibration level until the comparator outputs a jump signal, wherein the steady-state signal is a signal whose amplitude remains unchanged within a preset time, and the jump signal is a signal whose amplitude changes between a high level and a low level within the preset time.

In an embodiment, the transmit circuit configures the DC common-mode level to a level to be measured that is the same as or different from the reference level; the first switch is turned on and the second switch is turned off, so that the first input terminal of the comparator receives the level to be measured, and the second input terminal of the comparator receives the reference level; and the comparator compares the level to be measured with the reference level, to obtain a comparison result.

In an embodiment, a control terminal of the first switch and a control terminal of the second switch are for receiving an enable signal, and in response to the enable signal being at a first level, the first switch is turned off and the second switch is turned on; and in response to the enable signal being at a second level, the first switch is turned on and the second switch is turned off.

In an embodiment, the transmit circuit comprises N first circuits, each first circuit comprises a fifth transistor, a sixth transistor, a first resistor, a second resistor, and a third resistor, a first terminal of the fifth transistor is connected to a high level, a second terminal of the fifth transistor is connected to a first terminal of the first resistor, a second terminal of the first resistor is connected to a first terminal of the second resistor and a first terminal of the third resistor, a second terminal of the second resistor is connected to a first terminal of the sixth transistor, a second terminal of the sixth transistor is grounded, a control terminal of the fifth transistor is for receiving a first control signal, and a control terminal of the sixth transistor is for receiving a second control signal, second terminals of N third resistors are connected to output the DC common-mode level, where N is a positive integer.

In an embodiment, the comparator comprises a dynamic comparator and a linear comparator.

According to an aspect of the present disclosure, an offset calibration method is provided, wherein the offset calibration method is applied to an offset calibration circuit, the offset calibration circuit is for calibrating a comparator, the offset calibration circuit comprises a first switch and a second switch, a first terminal of the first switch is for receiving a reference level, a first terminal of the second switch is connected to a first input terminal of the comparator to receive a DC common-mode level, a second terminal of the first switch, a second terminal of the second switch, and a second input terminal of the comparator are connected to each other, and the DC common-mode level is from a transmit circuit; and the method comprises: configuring, by the transmit circuit, the DC common-mode level to be a same calibration level as the reference level; turning off the first switch and turning on the second switch, wherein both the first input terminal and the second input terminal of the comparator are for receiving the calibration level; and calibrating the comparator according to the calibration level until the comparator outputs a jump signal, wherein the jump signal is for indicating that offset calibration for the comparator is completed.

In an embodiment, the calibrating the comparator according to the calibration level until the comparator outputs the jump signal comprises: in a case that the comparator outputs a steady-state signal, the comparator performs calibration according to the calibration level until the comparator outputs a jump signal, wherein the steady-state signal is a signal whose amplitude remains unchanged within a preset time, and the jump signal is a signal whose amplitude changes between a high level and a low level within the preset time.

In an embodiment, the method further comprises: configuring, by the transmit circuit, the DC common-mode level to a level to be measured that is the same as or different from the reference level; turning on the first switch and turning off the second switch, so that the first input terminal of the comparator receives the level to be measured, and the second input terminal of the comparator receives the reference level; and comparing, by the comparator, the level to be measured with the reference level, to obtain a comparison result.

In an embodiment, a control terminal of the first switch and a control terminal of the second switch are for receiving an enable signal, and in response to the enable signal being at a first level, the first switch is turned off and the second switch is turned on; and in response to the enable signal being at a second level, the first switch is turned on and the second switch is turned off.

In an embodiment, the transmit circuit comprises N first circuits, each first circuit comprises a fifth transistor, a sixth transistor, a first resistor, a second resistor, and a third resistor, a first terminal of the fifth transistor is connected to a high level, a second terminal of the fifth transistor is connected to a first terminal of the first resistor, a second terminal of the first resistor is connected to a first terminal of the second resistor and a first terminal of the third resistor, a second terminal of the second resistor is connected to a first terminal of the sixth transistor, a second terminal of the sixth transistor is grounded, a control terminal of the fifth transistor is for receiving a first control signal, and a control terminal of the sixth transistor is for receiving a second control signal, second terminals of N third resistors are connected to output the DC common-mode level, where N is a positive integer.

In an embodiment, the comparator comprises a dynamic comparator and a linear comparator.

According to an aspect of the present disclosure, there is provided a chip comprising the offset calibration circuit as described above.

According to an aspect of the present disclosure, there is provided an electronic device comprising the offset calibration circuit as described above.

The offset calibration circuit of the embodiment of the present disclosure is for calibrating a comparator, and the offset calibration circuit comprises a first switch and a second switch, a first terminal of the first switch is for receiving a reference level, a first terminal of the second switch is connected to a first input terminal of the comparator to receive a DC common-mode level, and a second terminal of the first switch, a second terminal of the second switch, and a second input terminal of the comparator are connected to each other. The offset calibration circuit of the embodiment of the present disclosure changes the switch connection mode of the input terminal of the comparator, and reduces the number of switches on the input signal line, so that the data signal (for example, a DC common-mode level) may be directly connected to an input terminal of a comparator, which is beneficial to reduce parasitic resistance and capacitance of an input path of the comparator, reduce attenuation of the data signal, and reduce a bit error rate of the system (for example, various systems comprising the comparator).

It is to be understood that both the foregoing general description and the following detailed description are exemplary and explanatory only and are not restrictive of the disclosure. Other features and aspects of the present disclosure will become apparent from the following detailed description of exemplary embodiments with reference to the accompanying drawings.

### BRIEF DESCRIPTION OF THE DRAWINGS

The accompanying drawings herein, which are incorporated in and constitute a part of this specification, illustrate embodiments consistent with the present disclosure and, together with the description, serve to explain the technical solutions of the present disclosure.

FIG. 1 shows a schematic diagram of an offset calibration circuit in the related art.

FIG. 2 shows a schematic diagram of an offset calibration circuit according to an embodiment of the present disclosure.

FIG. 3 shows a schematic diagram of a transmit circuit according to an embodiment of the present disclosure.

FIG. 4 shows a schematic circuit diagram of an offset calibration for a comparator according to an embodiment of the present disclosure.

FIG. 5 shows a flowchart of an offset calibration method according to an embodiment of the present disclosure.

### DETAILED DESCRIPTION

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

Various exemplary embodiments, features and aspects of the present disclosure will be described in detail below with reference to the accompanying drawings. The same reference numbers in the drawings indicate functionally the same or similar elements. While the various aspects of the embodiments are presented in drawings, the drawings are not necessarily drawn to scale unless specifically indicated.

The word “exemplary” is used exclusively herein to mean “serving as an example, embodiment, or illustration.” Any embodiment described herein as “exemplary” is not necessarily to be construed as preferred or advantageous over other embodiments.

In the description of the present disclosure, it should be understood that the orientation or positional relationship indicated by the terms “length”, “width”, “upper”, “lower”, “front”, “rear”, “left”, “right”, “vertical”, “horizontal”, “top”, “bottom”, “inner”, “outer”, etc. is the orientation or positional relationship shown based on the drawings, and is only for the convenience of describing the present disclosure and simplifying the description, rather than indicating or implying that the apparatus or element referred to must have a specific orientation, be constructed and operated in a specific orientation, and therefore cannot be understood as a limitation to the present disclosure.

In addition, the terms “first” and “second” are only used for descriptive purposes, and cannot be understood as indicating or implying relative importance or implicitly indicating the number of indicated technical features. Therefore, features defined with “first” and “second” may explicitly or implicitly comprise one or more of the features. In the description of the present disclosure, “a plurality of” means two or more than two, unless otherwise specifically defined.

In the present disclosure, unless otherwise expressly specified and limited, the terms “mounted”, “connected with”, “connected”, “fixed” and the like should be understood in a broad sense, for example, it may be a fixed connection, a detachable connection, or an integral connection; it may be a mechanical connection or an electrical connection; it may be a direct connection or an indirect connection through an intermediate medium; it may be an internal communication between two elements or an interaction relationship between two elements. For those of ordinary skill in the art, the specific meanings of the above terms in the present disclosure can be understood according to specific situations.

It should be understood that in the following description, “circuitry” may comprise a single or a plurality of combined hardware circuits, programmable circuits, state machine circuits and/or elements capable of storing instructions executed by programmable circuits. When an element or circuit is referred to as being “connected to” another element or “connected between” two nodes, it may be directly coupled or connected to the other element or intervening elements may be present, and the connection between elements may be physical, logical, or a combination thereof. In contrast, when an element is referred to as being “directly coupled to” or “directly connected to” another element, there are no intervening elements present therebetween.

The term “and/or” herein is merely an association relationship for describing associated objects, and indicates that three relationships may exist, for example, A and/or B may indicate three cases: A exists alone, both A and B exist, and B exists alone. In addition, the term “at least one” herein indicates any one or any combination of at least two of a plurality, for example, comprising at least one of A, B, or C may indicate comprising any one or more elements selected from a set comprising A, B, and C.

It should be noted that the transistors used in all embodiments of the present disclosure may be thin film transistors or field effect transistors or other devices with the same characteristics, and the transistors used in the embodiments of the present disclosure are mainly switching transistors according to the function in the circuit. Since the source and the drain of the switching transistor used herein are symmetrical, the source and the drain are interchangeable, and the source is referred to as the first terminal and the drain is referred to as the second terminal, or the drain is referred to as the first terminal and the source is referred to as the second terminal. For example, according to the form in the drawings, it may be specified that the middle terminal of the transistor is the gate, the signal input terminal is the source, and the signal output terminal is the drain. In addition, the switching transistor used in the embodiments of the present disclosure may comprise any one or a combination of a P-type transistor and an N-type transistor. The P-type transistor is turned on when the gate is at a low voltage and cut off when the gate is at a high voltage, and the N-type transistor is turned on when the gate is at a high voltage and cut off when the gate is at a low voltage. In addition, the plurality of signals in each embodiment may correspond to a first potential and a second potential, and the first potential and the second potential only represent that the potential of the signal has two different state quantities, and do not represent that the first potential or the second potential has a specific value.

In addition, in order to better illustrate the present disclosure, numerous specific details are given in the following specific embodiments. It will be understood by those skilled in the art that the present disclosure may be implemented without some of the specific details. In some examples, methods, means, elements and circuits well known to those skilled in the art are not described in detail, so as to highlight the subject matter of the present disclosure.

For the high-speed comparator circuit, in order to optimize the performance of the comparator, the receiver will add equalization technologies, comprising but not limited to a continuous time linear equalizer (CTLE) circuit and a decision feedback equalizer (DFE) circuit. Adding various equalization technologies optimizes the circuit bandwidth and reduces the error rate of the circuit, but since various functional circuits are added, the offset of the circuit will also increase, so the comparator of the receiver may be calibrated before the high-speed receiver operates normally, thereby improving the system performance.

The offset calibration solution in the related art is usually adapted to a low-speed comparator, a matching control switch may be added on a differential signal line of the comparator, and the differential signal may be simultaneously connected to a same reference voltage by the control switch. Since a plurality of switches (for example, at least four switches) are connected in series on the signal line and each switch has parasitic capacitance and resistance, high-frequency signal attenuation may be caused, and a bit error rate of a system is increased.

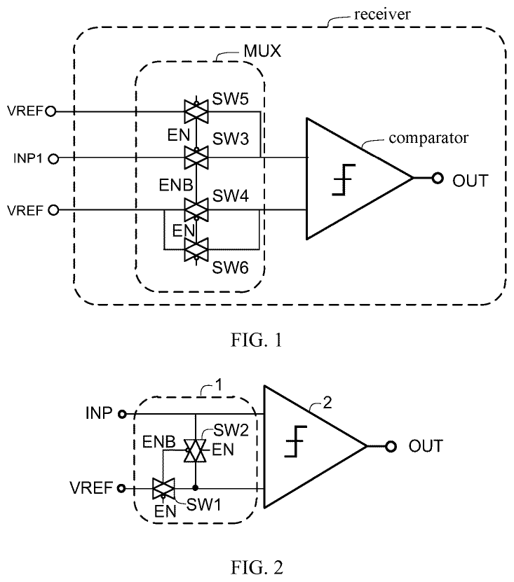

FIG. 1 shows a schematic diagram of an offset calibration circuit in the related art, as shown in FIG. 1, the receiver may comprise an offset calibration circuit MUX and a comparator, and the offset calibration circuit MUX comprises a switch SW3, a switch SW4, a switch SW5, and a switch SW6, where a first terminal of the switch SW3 is for receiving an input signal INP1, a second terminal of the switch SW3 is connected to a first input terminal (a non-inverting input terminal) of the comparator, a first terminal of the switch SW4 is for receiving a reference level VREF, a second terminal of the switch SW4 is connected to a second input terminal (a inverting input terminal) of the comparator, a first terminal of the switch SW5 is for receiving the reference level VREF, a second terminal of the switch SW5 is connected to the first input terminal (the non-inverting input terminal) of the comparator, a first terminal of the switch SW6 is for receiving the reference level VREF, and a second terminal of the switch SW6 is connected to the second input terminal (the inverting input terminal) of the comparator.

The input terminals of the comparator can be controlled by four switches (i.e., switch SW3, switch SW4, switch SW5 and switch SW6), and when the comparator operates normally, switch SW3 and switch SW4 are turned on, and switch SW5 and switch SW6 are kept off. During the offset calibration, the switch SW3 and the switch SW4 are turned off, and the switch SW5 and the switch SW6 are turned on, so that the signals at the differential input terminals of the comparator are equal, and then the offset calibration for the comparator is performed.

The switch enable signal may be configured to indicate on/off states of the switch SW3, the switch SW4, the switch SW5, and the switch SW6; if the enable signal is at the first level EN, the switch SW3 and the switch SW4 are turned off, and the switch SW5 and the switch SW6 are turned on; and if the enable signal is at the second level ENB, the switch SW3 and the switch SW4 are turned on, and the switch SW5 and the switch SW6 are turned off. It should be understood that the first level EN and the second level ENB only represent that the potential of the signal has two different state quantities, and do not represent that the signal has a specific value.

It can be seen from FIG. 1 that the calibration method in the related art limits the data transmission rate, and in order to calibrate the offset of the signal, a plurality of control switches (for example, switch SW3, switch SW4, switch SW5 and switch SW6 in FIG. 1) are added to the input signal path. The on-resistance and parasitic capacitance of the switches will reduce the bandwidth of the signal path, and the high-speed signal quality passing through the switches will be reduced, so the bandwidth of the receiver will also be reduced, and the bit error rate of the circuit will also be increased.

FIG. 2 shows a schematic diagram of an offset calibration circuit according to an embodiment of the present disclosure, as shown in FIG. 2, the offset calibration circuit 1 is for calibrating a comparator 2, the offset calibration circuit 1 comprises a first switch SW1 and a second switch SW2, a first terminal of the first switch SW1 is for receiving a reference level VREF, a first terminal of the second switch SW2 is connected to a first input terminal (a non-inverting input terminal) of the comparator 2 to receive a DC common-mode level INP, and a second terminal of the first switch SW1, a second terminal of the second switch SW2, and a second input terminal (a inverting input terminal) of the comparator 2 are connected to each other.

Compared with the offset calibration technology shown in FIG. 1, in the related art, the high-speed input signal INP1 enters the receiver, and switches (for example, the switch SW3, the switch SW4, the switch SW5, and the switch SW6 in FIG. 1) are added to the signal line at the input terminals of the comparator, which introduces parasitic resistance and capacitance to the input signal line, so that the bandwidth of the input signal is reduced, and the bit error rate of the receiver is increased. On the contrary, the offset calibration circuit of the embodiment of the present disclosure changes the switch connection mode of the input terminals of the comparator 2 in FIG. 1, and reduces the number of switches on the input signal line, so that the data signal (for example, the DC common-mode level INP) can be directly connected to the input terminal of the comparator 2, which is beneficial to reduce the parasitic resistance and capacitance of an input path of the comparator 2, reduce attenuation of the data signal, and reduce a bit error rate of the systems (for example, various systems comprising the comparator).

It should be understood that for the high-speed signal receiver comprising the comparator 2, the high-speed signal line needs to reduce the parasitic resistance and capacitance as much as possible, and the offset calibration circuit of the embodiment of the present disclosure can reduce the series resistance on the high-speed signal.

In an embodiment, the comparator 2 is for comparing two voltages or signals, and outputting a corresponding logic level. For example, the comparator 2 is a circuit that compares an analog voltage signal (e.g., the DC common-mode level INP) with a reference voltage (e.g., the reference level VREF). Two inputs of the comparator 2 are analog signals, an output terminal OUT outputs a binary signal 0 or 1, and when a difference between input voltages (for example, a difference between the DC common-mode level INP and the reference level VREF) increases or decreases and positive and negative signs remain unchanged, an output of the comparator 2 remains unchanged.

In an embodiment, the offset calibration circuit of the embodiment of the present disclosure is applicable to a high frequency system such as a double data rate synchronous dynamic random access memory (DDR SDRAM) communication interface (IO) system and a flash (NAND) communication interface (IO) system, and may perform offset calibration on a comparator in the system without reducing a bandwidth design requirement.

In an embodiment, the comparator 2 comprises a dynamic comparator and a linear comparator, the embodiments of the present disclosure do not limit the type of the comparator, and the offset calibration circuit provided by the embodiments of the present disclosure can be applied to various comparators.

For the circuit of the comparator 2, when performing offset calibration on it, the differential input signal needs to keep inputting the same level signal, for example, the first input terminal and the second input terminal of the comparator 2 are input the same level signal, and by observing the state of the differential output terminal OUT, it is determined that the circuit offset of the comparator 2 is biased toward the non-inverting terminal or the inverting terminal.

In the case where the comparator 2 is a linear comparator, if the same common-mode level signal (for example, the DC common-mode level INP is the same as the reference level VREF) is input differentially, and the output of the linear comparator remains 1 or 0, it indicates that the offset of the linear comparator circuit is biased toward the non-inverting terminal or the inverting terminal, and the calibration module of the linear comparator may be adjusted to make the output of the linear comparator jump from 0 to 1 or jump from 1 to 0, and at this time, the offset calibration for the linear comparator circuit is completed.

In the case where the comparator 2 is a dynamic comparator, by inputting a sampling clock, if the output of the dynamic comparator maintains a state of 0 or 1, it is necessary to perform offset calibration and adjust the calibration module of the dynamic comparator; when the output terminal of the dynamic comparator jumps, from 0 to 1 or from 1 to 0, the offset calibration for the dynamic comparator circuit is completed.

In an embodiment, the control terminal of the first switch SW1 and the control terminal of the second switch SW2 are for receiving an enable signal, and in response to the enable signal being at a first level EN, turn off the first switch SW1 and turn on the second switch SW2; and in response to the enable signal being at a second level ENB, turn on the first switch SW1 and turn off the second switch SW2.

Exemplarily, the first switch SW1 (or the second switch SW2) may be composed of at least one switch transistor, and in the case where the number of switch transistors constituting the first switch SW1 (or the second switch SW2) exceeds one, the switch transistors may be connected in series or in parallel, which is not specifically limited in the embodiments of the present disclosure. It should be understood that, in order to reduce the parasitic resistance and parasitic capacitance of the input path of the comparator 2, preferably, a single switching transistor is used as the first switch SW1 (or the second switch SW2).

The control terminal of the switch transistor is a gate, the first terminal may be a source, and the second terminal may be a drain; or the first terminal may be a drain, and the second terminal may be a source, which are not specifically distinguished herein. Further, in a specific implementation, the N-type transistor is turned on under the action of a high-level signal and cut off under the action of a low-level signal. The P-type transistor is cut off under the action of a high-level signal and turned on under the action of a low-level signal.

For example, the N-type transistor may be used as the first switch SW1, the P-type transistor may be used as the second switch SW2, the first level EN may be set to a low level, and the second level ENB may be set to a high level.

A gate of the first switch SW1 (for example, an N-type transistor) is controlled by a low level, and the first switch SW1 is in an off state; a gate of the second switch SW2 (for example, a P-type transistor) is controlled by a low level, and the second switch SW2 is in an on state.

A gate of the first switch SW1 (for example, an N-type transistor) is controlled by a high level, and the first switch SW1 is in an on state; a gate of the second switch SW2 (for example, a P-type transistor) is controlled by a high level, and the second switch SW2 is in an off state.

For another example, the P-type transistor may be used as the first switch SW1, the N-type transistor may be used as the second switch SW2, the first level EN is set to a high level, and the second level ENB is set to a low level.

A gate of the first switch SW1 (for example, a P-type transistor) is controlled by a high level, and the first switch SW1 is in an off state; a gate of the second switch SW2 (for example, an N-type transistor) is controlled by a high level, and the second switch SW2 is in an on state.

A gate of the first switch SW1 (for example, a P-type transistor) is controlled by a low level, and the first switch SW1 is in an on state; a gate of the second switch SW2 (for example, an N-type transistor) is controlled by a low level, and the second switch SW2 is in an off state.

It should be understood that the first level EN and the second level ENB only represent that the potential of the enable signal has two different state quantities, and do not represent that the enable signal has a specific value. The specific structures of the first switch SW1 and the second switch SW2 provided by the embodiments of the present disclosure have been described above only by way of examples, and are not limited to the above structures provided by the embodiments of the present disclosure during specific implementation, and may be adjusted according to actual application scenarios, which is not limited herein.

The on/off states of the two switches (for example, the first switch SW1 and the second switch SW2) can be flexibly controlled by different level states of the enable signal, and this control manner helps make a circuit design more flexible, improve circuit reliability, reduce power consumption, and simplify a circuit design.

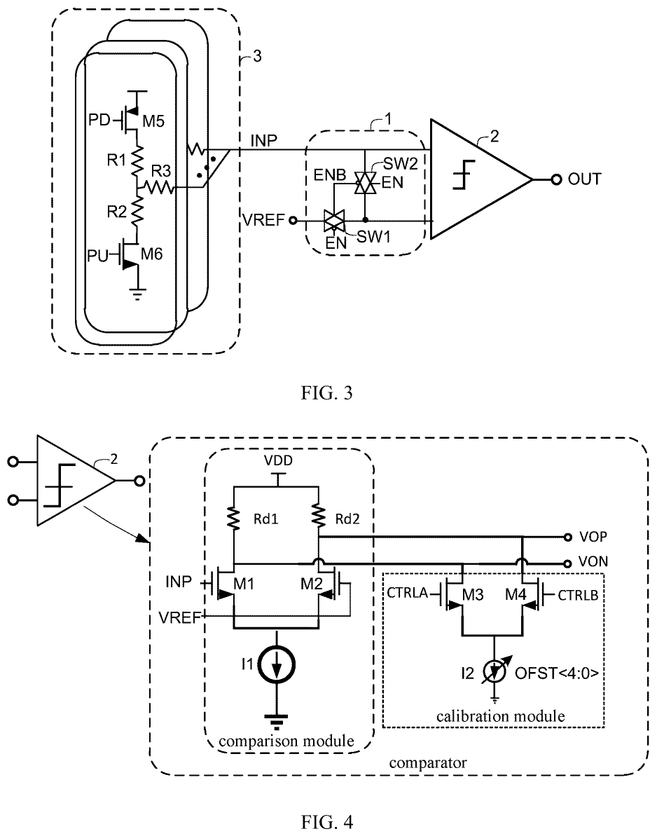

In an embodiment, the DC common-mode level INP comprises a high-speed signal with a transmission rate higher than a preset threshold, and the DC common-mode level INP comes from a transmit circuit. FIG. 3 shows a schematic diagram of a transmit circuit according to an embodiment of the present disclosure. As shown in FIG. 3, the transmit circuit 3 comprises N first circuits, each first circuit comprises a fifth transistor M5 (for example, a P-type transistor), a sixth transistor M6 (for example, an N-type transistor), a first resistor R1, a second resistor R2, and a third resistor R3, a first terminal (for example, a source) of the fifth transistor M5 is connected to a high level (for example, a high level provided by a power supply), a second terminal (for example, a drain) of the fifth transistor M5 is connected to a first terminal of the first resistor R1, a second terminal of the first resistor R1 is connected to a first terminal of the second resistor R2 and a first terminal of the third resistor R3, a second terminal of the second resistor R2 is connected to a first terminal (for example, a drain) of the sixth transistor M6, a second terminal (for example, a source) of the sixth transistor M6 is grounded, a control terminal (for example, a gate) of the fifth transistor M5 is for receiving a first control signal PD, a control terminal (for example, a gate) of the sixth transistor M6 is for receiving a second control signal PU, and the second terminals of N third resistors R3 are connected to output the DC common-mode level INP, where N is a positive integer.

According to a principle of voltage division by resistors, by controlling the first control signal PD and the second control signal PU corresponding to each first circuit in the transmit circuit 3, the switching states (for example, on or off) of the fifth transistor M5 and the sixth transistor M6 in each first circuit can be controlled, various resistor voltage division ratios can be formed, and a desired target amplitude level is configured as the DC common-mode level INP.

In an embodiment, operating statuses of a power supply and a ground wire of the comparator 2 and the transmit circuit 3 may be determined, and in a comparator calibration phase, the transmit circuit 3 configures the DC common-mode level INP to a calibration level the same as the reference level VREF; the first switch SW1 is turned off, and the second switch SW2 is turned on, so that the first input terminal (a non-inverting input terminal) and the second input terminal (a inverting input terminal) of the comparator 2 receive the calibration level; and the comparator 2 performs calibration based on the calibration level until the comparator 2 outputs a jump signal, where the jump signal is for indicating that offset calibration for the comparator 2 is completed.

Because the output terminal of the transmit circuit 3 and the first input terminal (the non-inverting input terminal) of the comparator 2 are directly connected through no switch, there is no parasitic resistance and parasitic capacitance introduced by the switch on a path on which the first input terminal (the non-inverting input terminal) of the comparator 2 is located, which is beneficial to perform offset calibration on the comparator 2 without reducing a bandwidth design requirement, reduce a probability of attenuation of a high-frequency input signal, and improve calibration accuracy of the comparator 2.

In the calibration phase, the first and second input terminals of the comparator 2 both receive the calibration level INP, that is, the input levels of the two input terminals are strictly consistent to ensure the accuracy of calibration. At the same time, the DC common-mode level INP is configured to be the same calibration level as the reference level VREF, so that the calibrated comparator has high accuracy when operating at the reference level VREF.

FIG. 4 shows a schematic circuit diagram of a comparator performing offset calibration according to an embodiment of the present disclosure. As shown in FIG. 4, the comparator 2 comprises a comparison module and a calibration module, and the comparison module comprises a first differential resistor Rd1, a second differential resistor Rd2, a first transistor M1, a second transistor M2, and a first current source I1; and the calibration module comprises a third transistor M3, a fourth transistor M4, and a second current source I2.

A first terminal of the first differential resistor Rd1 and a first terminal of the second differential resistor Rd2 are connected to receive the power signal VDD, a second terminal of the first differential resistor Rd1, a drain of the first transistor M1, and a drain of the third transistor M3 are connected to provide an inverting output signal VON, a second terminal of the second differential resistor Rd2, a drain of the second transistor M2, and a drain of the fourth transistor M4 are connected to provide a non-inverting output signal VOP, a gate of the first transistor M1 may serve as a first input terminal (a non-inverting input terminal) of the comparator 2 to receive the DC common-mode level INP, a gate of the second transistor M2 may serve as a second input terminal (a inverting input terminal) of the comparator 2 to receive the reference level VREF, a source of the first transistor M1 and a source of the second transistor M2 are connected to a first terminal of the first current source I1, a source of the third transistor M3 and a source of the fourth transistor M4 are connected to a first terminal of the second current source 12, a gate of the third transistor M3 receives a third control signal CTRLA, a gate of the fourth transistor M4 receives a fourth control signal CTRLB, and a second terminal of the first current source I1 and a second terminal of the second current source 12 are connected to the ground.

The comparator 2 may perform offset calibration by changing currents passing through the first differential resistor Rd1 and the second differential resistor Rd2. For example, the register for offset calibration for the comparator 2 may be set to OFST <M: 0>, and by changing the register control word OFST <M: 0>, the third transistor M3 or the fourth transistor M4 is selected to be turned on, the magnitude of the current of the second current source I2 is changed, the current values flowing through the first differential resistor Rd1 and the second differential resistor Rd2 are adjusted, and the common-mode level of the differential output (see VOP, VON in FIG. 4) of the comparator 2 is changed until the comparator 2 outputs a jump signal, indicating that the calibration for the comparator is completed. M is a positive integer, indicating that the register OFST <M: 0>is an M+1 bits register, and the embodiments of the present disclosure do not limit the number of bits of the register, which may be set according to actual application scenarios.

By controlling the first switch SW1 and the second switch SW2, the comparator 2 can be switched to the calibration state more quickly and flexibly.

In an embodiment, the calibrating the comparator 2 according to the calibration level until the comparator 2 outputs the jump signal comprises: in a case that the comparator 2 outputs a steady-state signal, performing, by the comparator 2, calibration according to the calibration level until the comparator 2 outputs a jump signal, where the steady-state signal is a signal whose amplitude remains unchanged within a preset time, and the jump signal is a signal whose amplitude changes between a high level and a low level within the preset time.

In a case that the first input terminal (the non-inverting input terminal) and the second input terminal (the inverting input terminal) of the comparator 2 receive the same signal (for example, the calibration level), if the comparator 2 outputs a steady-state signal, it indicates that the comparator 2 outputs an incorrect result, and the comparator 2 needs to be calibrated; and if the comparator 2 outputs a jump signal, it indicates that the comparator 2 outputs a correct result, the comparator 2 does not need to be calibrated, and the comparator 2 may be directly used to perform a comparison operation.

In order to improve the calibration efficiency of the comparator 2, in a case that the first input terminal (the non-inverting input terminal) and the second input terminal (the inverting input terminal) of the comparator 2 receive the same signal (e.g., the calibration level), the output signal state of the comparator 2 may be determined first. If the comparator 2 outputs the jump signal, the calibration link may be omitted, and the comparator 2 is directly used to perform the comparison task. If the comparator 2 outputs a steady-state signal, the comparator 2 may be calibrated according to the calibration level until the comparator 2 outputs a jump signal.

For example, assuming that the comparator 2 is a dynamic comparator, the output data of the comparator 2 can be read through a sampling clock, and if the output remains a steady-state signal, for example, 0 or 1, the calibration module of the comparator 2 can be enabled, and the register control word can be scanned until the state of the output signal of the comparator 2 jumps from 0 to 1 or from 1 to 0; and the register configuration is recorded and stored, and the calibration for the comparator 2 is completed.

For example, assuming that the comparator 2 is a linear comparator, the output data of the comparator 2 can be directly read (without involving the sampling clock), and if the output signal remains a steady-state signal, for example, 0 or 1, the calibration module of the comparator 2 can be enabled, and the register control word can be scanned until the state of the output signal of the comparator 2 jumps from 0 to 1 or from 1 to 0; and the register configuration is recorded and stored, and the calibration for the comparator 2 is completed.

This manner of determining whether to calibrate the comparator 2 by determining the output signal state of the comparator 2 can improve the calibration efficiency.

After the calibration for the comparator 2 is completed, the comparator 2 can operate normally and accurately compare the level to be measured received by its first input terminal (the non-inverting input terminal) with the reference level VREF received by the second input terminal (the inverting input terminal).

In an embodiment, in a comparison phase after calibration is completed, the transmit circuit 3 configures the DC common-mode level INP to a level to be measured that is the same as or different from the reference level VREF; the first switch SW1 is turned on, and the second switch SW2 is turned off, so that a first input terminal (a non-inverting input terminal) of the comparator 2 receives the level to be measured, and a second input terminal (a inverting input terminal) of the comparator 2 receives the reference level VREF; and the comparator 2 compares the level to be measured with the reference level VREF, to obtain a comparison result.

For example, if the level to be measured is higher than the reference level VREF, the comparison result output by the comparator 2 is a high level (e.g., 1). If the level to be measured is lower than the reference level VREF, the comparison result output by the comparator 2 is a low level (e.g., 0). If the level to be measured is equal to the reference level VREF, the comparison result output by the comparator 2 is a jump signal (jump from 0 to 1 or jump from 1 to 0).

By controlling the first switch SW1 and the second switch SW2, the comparator 2 can be switched from the calibration state to the normal operating state more quickly and flexibly.

In summary, the offset calibration circuit of the embodiment of the present disclosure changes the switch connection mode of the input terminal of the comparator 2, and reduces the number of switches on the input signal line, for example, the switches (for example, the switch SW3 in FIG. 1) on the data signal line are removed, and the data signal (for example, the DC common-mode level INP) can be directly connected to the input pair of transistors of the comparator 2, which is beneficial to reduce the parasitic resistance and capacitance of the input path of the comparator 2, reduce the attenuation of the data signal, and reduce a bit error rate of the system.

It can be understood that the above embodiments mentioned in the present disclosure can be combined with each other to form a combined embodiment without departing from the principle and logic, which will not be repeated in the present disclosure due to space limitations.

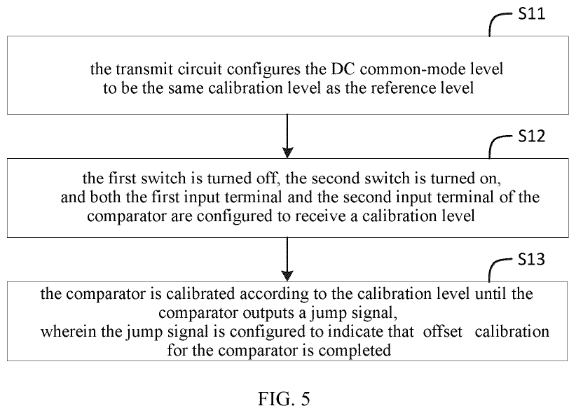

FIG. 5 shows a flowchart of an offset calibration method according to an embodiment of the present disclosure. As shown in FIG. 5, the offset calibration method is applied to the offset calibration circuit 1 shown in FIG. 2, the offset calibration circuit 1 is for calibrating a comparator 2, the offset calibration circuit 1 comprises a first switch SW1 and a second switch SW2, a first terminal of the first switch SW1 is for receiving a reference level VREF, a first terminal of the second switch SW2 is connected to a first input terminal of the comparator 2 to receive a DC common-mode level INP, a second terminal of the first switch SW1, a second terminal of the second switch SW2, and a second input terminal of the comparator 2 are connected to each other, and the DC common-mode level INP comes from a transmit circuit 3, and the method comprises:
In operation S11, the transmit circuit 3 configures the DC common-mode level INP to be the same calibration level as the reference level VREF;
In operation S12, the first switch SW1 is turned off, the second switch SW2 is turned on, and both the first input terminal and the second input terminal of the comparator 2 are configured to receive a calibration level;
In operation S13, the comparator 2 is calibrated according to the calibration level until the comparator 2 outputs a jump signal, where the jump signal is for indicating that offset calibration for the comparator 2 is completed.

The method has a specific technical association with the internal structure of the computer system, and can solve the technical problem of how to improve the hardware operation efficiency or execution effect (including reducing the amount of data storage, reducing the amount of data transmission, improving the hardware processing speed, etc.), thereby obtaining the technical effect of improving the internal performance of the computer system conforming to natural laws.

In an embodiment, operation S13 may comprise: in a case that the comparator 2 outputs a steady-state signal, the comparator 2 performs calibration according to the calibration level until the comparator 2 outputs a jump signal, where the steady-state signal is a signal whose amplitude remains unchanged within a preset time, and the jump signal is a signal whose amplitude changes between a high level and a low level within the preset time.

In an embodiment, the method further comprises: configuring, by the transmit circuit 3, the DC common-mode level INP to a level to be measured that is the same as or different from the reference level VREF; turning on the first switch SW1, and turning off the second switch SW2, so that a first input terminal of the comparator 2 receives the level to be measured, and a second input terminal of the comparator 2 receives the reference level VREF; and comparing, by the comparator 2, the level to be measured with the reference level VREF, to obtain a comparison result.

In an embodiment, the control terminal of the first switch SW1 and the control terminal of the second switch SW2 are for receiving an enable signal, and in response to the enable signal being at a first level EN, the first switch SW1 is turned off and the second switch SW2 is turned on; and in response to the enable signal being at a second level ENB, the first switch SW1 is turned on and the second switch SW2 is turned off.

In an embodiment, as shown in FIG. 3, the transmit circuit 3 comprises N first circuits, each first circuit comprises a fifth transistor M5, a sixth transistor M6, a first resistor R1, a second resistor R2, and a third resistor R3, a first terminal of the fifth transistor M5 is connected to a high level, a second terminal of the fifth transistor M5 is connected to a first terminal of the first resistor R1, a second terminal of the first resistor R1 is connected to a first terminal of the second resistor R2 and a first terminal of the third resistor R3, a second terminal of the second resistor R2 is connected to a first terminal of the sixth transistor M6, a second terminal of the sixth transistor M6 is grounded, a control terminal of the fifth transistor M5 is for receiving a first control signal PD, a control terminal of the sixth transistor M6 is for receiving a second control signal PU, and second terminals of N third resistors R3 are connected to output the DC common-mode level INP, and N is a positive integer.

In an embodiment, the comparator 2 comprises a dynamic comparator and a linear comparator.

In some embodiments, functions or modules of the apparatus provided in the embodiments of the present disclosure may be for performing the method described in the above method embodiments, and for specific implementation thereof, reference may be made to the description of the above method embodiments, which will not be repeated here for brevity.

According to another aspect of the present disclosure, there is provided a chip comprising the offset calibration circuit 1 as described above.

According to another aspect of the present disclosure, there is provided an electronic device comprising the offset calibration circuit 1 as described above. The electronic device may be a mobile phone, a computer, a digital broadcast terminal, a messaging device, a game console, a tablet device, a medical device, a fitness device, a personal digital assistant, etc., which is not limited in the present disclosure.

Based on a same concept, this application further provides a terminal device, comprising a housing, a processor, a memory, and an analog-to-digital converter having the offset calibration circuit 1 in the foregoing embodiment, where the processor and the memory are disposed in the housing, the memory is coupled to the processor, and the analog-to-digital converter having the offset calibration circuit 1 is for converting an analog signal into a digital signal and inputting the digital signal to the processor; and the processor is for processing the digital signal.

The terminal device may be any product or component having a data processing function, such as a mobile phone, a tablet computer, a television, a display, a notebook computer, user equipment (UE), a mobile device, a user terminal, a terminal, a cellular phone, a cordless phone, a personal digital assistant (PDA), a handheld device, a computing device, a vehicle-mounted device, or a wearable device. Other essential components of the terminal device should be understood by a person of ordinary skill in the art, and details are not described herein again, and should not be used as a limitation on this application.

A person skilled in the art should understand that the embodiments of this application may be provided as a method, a system, or a computer program product. Therefore, the present disclosure may take the form of an entirely hardware embodiment, an entirely software embodiment, or an embodiment combining software and hardware aspects. In addition, this application may take a form of a computer program product implemented on one or more computer-usable storage media (including but not limited to a disk memory, a CD-ROM, an optical memory, and the like) that comprise computer-usable program code.

This application is described with reference to flowcharts and/or block diagrams of the method, the device (system), and the computer program product according to this application. It will be understood that each flow and/or block of the flowcharts and/or block diagrams, and combinations of flows and/or blocks in the flowcharts and/or block diagrams, can be implemented by computer program instructions. These computer program instructions may be provided to a processor of a general-purpose computer, a special-purpose computer, an embedded processor, or other programmable data processing device to generate a machine, so that the instructions executed by the processor of the computer or the other programmable data processing device generate an apparatus for implementing functions specified in one or more flows in the flowcharts and/or one or more blocks in the block diagrams.

These computer program instructions may also be stored in a computer-readable memory that can guide a computer or other programmable data processing device to operate in a specific manner, so that the instructions stored in the computer-readable memory generate a product comprising an instruction apparatus, and the instruction apparatus implements a function specified in one or more flows in the flowcharts and/or one or more blocks in the block diagrams.

These computer program instructions may also be loaded onto a computer or other programmable data processing device to cause a series of operational steps to be executed on the computer or other programmable device to produce computer-implemented processing, such that the instructions executed on the computer or other programmable device provide steps for implementing the functions specified in one or more flows of the flowcharts and/or one or more blocks of the block diagrams.

It can be understood that the above method embodiments mentioned in the present disclosure can be combined with each other to form a combined embodiment without departing from the principle and logic, which will not be repeated in the present disclosure due to space limitations. A person skilled in the art may understand that, in the foregoing method in the specific implementation, a specific execution order of the steps should be determined based on functions and possible internal logic of the steps.

The foregoing descriptions of the embodiments tend to emphasize differences between the embodiments, the same or similar parts may be referred to each other, and for brevity, details are not described herein again.

Those skilled in the art can understand that in the above method of the specific embodiment, the writing order of each step does not mean a strict execution order and constitutes any limitation on the implementation process, and a specific execution order of the steps should be determined based on functions and possible internal logic of the steps.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An offset calibration circuit for calibrating a comparator, the offset calibration circuit comprising a first switch and a second switch,
wherein a first terminal of the first switch is configured to receive a reference level, a first terminal of the second switch is connected to a first input terminal of the comparator to receive a direct current (DC) common-mode level, and a second terminal of the first switch, a second terminal of the second switch, and a second input terminal of the comparator are connected to each other.

2. The circuit according to claim 1, wherein the DC common-mode level is from a transmit circuit, and the transmit circuit configures the DC common-mode level to be a same calibration level as the reference level;
wherein the first switch is turned off and the second switch is turned on to cause the first input terminal and the second input terminal of the comparator to receive the calibration level; and
wherein the comparator performs calibration according to the calibration level until the comparator outputs a jump signal, wherein the jump signal is configured to indicate that offset calibration for the comparator is completed.

3. The circuit according to claim 2, wherein calibrating the comparator according to the calibration level until the comparator outputs the jump signal comprises:
in a case that the comparator outputs a steady-state signal, the comparator performs the calibration according to the calibration level until the comparator outputs the jump signal, wherein the steady-state signal is a signal whose amplitude remains unchanged within a preset time, and the jump signal is a signal whose amplitude changes between a high level and a low level within the preset time.

4. The circuit according to claim 2, wherein the transmit circuit configures the DC common-mode level to a level to be measured that is the same as or different from the reference level;
wherein the first switch is turned on and the second switch is turned off to cause the first input terminal of the comparator to receive the level to be measured and to cause the second input terminal of the comparator to receive the reference level; and
wherein the comparator compares the level to be measured with the reference level to obtain a comparison result.

5. The circuit according to claim 1, wherein a control terminal of the first switch and a control terminal of the second switch are configured to receive an enable signal,
wherein in response to the enable signal being at a first level, the first switch is turned off and the second switch is turned on; and
wherein in response to the enable signal being at a second level, the first switch is turned on and the second switch is turned off.

6. The circuit according to claim 2, wherein the transmit circuit comprises N first circuits,
wherein each first circuit comprises a fifth transistor, a sixth transistor, a first resistor, a second resistor, and a third resistor, a first terminal of the fifth transistor is connected to a high level, a second terminal of the fifth transistor is connected to a first terminal of the first resistor, a second terminal of the first resistor is connected to a first terminal of the second resistor and a first terminal of the third resistor, a second terminal of the second resistor is connected to a first terminal of the sixth transistor, a second terminal of the sixth transistor is grounded, a control terminal of the fifth transistor is configured to receive a first control signal, and a control terminal of the sixth transistor is configured to receive a second control signal, and
wherein the second terminals of N third resistors are connected to output the DC common-mode level, where N is a positive integer.

7. The circuit according to claim 2, wherein the comparator comprises a dynamic comparator and a linear comparator.

8. An offset calibration method, wherein the offset calibration method is applied to an offset calibration circuit, the offset calibration circuit is configured to calibrate a comparator, the offset calibration circuit comprises a first switch and a second switch, a first terminal of the first switch is configured to receive a reference level, a first terminal of the second switch is connected to a first input terminal of the comparator to receive a direct current (DC) common-mode level, a second terminal of the first switch, a second terminal of the second switch, and a second input terminal of the comparator are connected to each other, and the DC common-mode level is from a transmit circuit, and
wherein the method comprises:
configuring, by the transmit circuit, the DC common-mode level to be a same calibration level as the reference level;
turning off the first switch and turning on the second switch, wherein both the first input terminal and the second input terminal of the comparator are configured to receive the calibration level; and
calibrating the comparator according to the calibration level until the comparator outputs a jump signal, wherein the jump signal is configured to indicate that offset calibration for the comparator is completed.

9. A chip comprising an offset calibration circuit for calibrating a comparator, the offset calibration circuit comprising a first switch and a second switch,
wherein a first terminal of the first switch is configured to receive a reference level, a first terminal of the second switch is connected to a first input terminal of the comparator to receive a direct current (DC) common-mode level, and a second terminal of the first switch, a second terminal of the second switch, and a second input terminal of the comparator are connected to each other.

10. An electronic device comprising an offset calibration circuit for calibrating a comparator, the offset calibration circuit comprising a first switch and a second switch,
wherein a first terminal of the first switch is configured to receive a reference level, a first terminal of the second switch is connected to a first input terminal of the comparator to receive a direct current (DC) common-mode level, and a second terminal of the first switch, a second terminal of the second switch, and a second input terminal of the comparator are connected to each other.

11. The chip according to claim 9, wherein the DC common-mode level is from a transmit circuit, and the transmit circuit configures the DC common-mode level to be a same calibration level as the reference level;
wherein the first switch is turned off and the second switch is turned on to cause the first input terminal and the second input terminal of the comparator to receive the calibration level; and
wherein the comparator performs calibration according to the calibration level until the comparator outputs a jump signal, wherein the jump signal is configured to indicate that offset calibration for the comparator is completed.

12. The chip according to claim 11, wherein calibrating the comparator according to the calibration level until the comparator outputs the jump signal comprises:
in a case that the comparator outputs a steady-state signal, the comparator performs the calibration according to the calibration level until the comparator outputs the jump signal, wherein the steady-state signal is a signal whose amplitude remains unchanged within a preset time, and the jump signal is a signal whose amplitude changes between a high level and a low level within the preset time.

13. The chip according to claim 11, wherein the transmit circuit configures the DC common-mode level to a level to be measured that is the same as or different from the reference level;
wherein the first switch is turned on and the second switch is turned off to cause the first input terminal of the comparator to receive the level to be measured and to cause the second input terminal of the comparator to receive the reference level; and
wherein the comparator compares the level to be measured with the reference level to obtain a comparison result.

14. The chip according to claim 9, wherein a control terminal of the first switch and a control terminal of the second switch are configured to receive an enable signal,
wherein in response to the enable signal being at a first level, the first switch is turned off and the second switch is turned on; and
wherein in response to the enable signal being at a second level, the first switch is turned on and the second switch is turned off.

15. The chip according to claim 11, wherein the transmit circuit comprises N first circuits,
wherein each first circuit comprises a fifth transistor, a sixth transistor, a first resistor, a second resistor, and a third resistor, a first terminal of the fifth transistor is connected to a high level, a second terminal of the fifth transistor is connected to a first terminal of the first resistor, a second terminal of the first resistor is connected to a first terminal of the second resistor and a first terminal of the third resistor, a second terminal of the second resistor is connected to a first terminal of the sixth transistor, a second terminal of the sixth transistor is grounded, a control terminal of the fifth transistor is configured to receive a first control signal, and a control terminal of the sixth transistor is configured to receive a second control signal, and
wherein the second terminals of N third resistors are connected to output the DC common-mode level, where N is a positive integer.

16. The chip according to claim 11, wherein the comparator comprises a dynamic comparator and a linear comparator.

17. The electronic device according to claim 10, wherein the DC common-mode level is from a transmit circuit, and the transmit circuit configures the DC common-mode level to be a same calibration level as the reference level;
wherein the first switch is turned off and the second switch is turned on to cause the first input terminal and the second input terminal of the comparator to receive the calibration level; and
wherein the comparator performs calibration according to the calibration level until the comparator outputs a jump signal, wherein the jump signal is configured to indicate that offset calibration for the comparator is completed.

18. The electronic device according to claim 17, wherein calibrating the comparator according to the calibration level until the comparator outputs the jump signal comprises:
in a case that the comparator outputs a steady-state signal, the comparator performs the calibration according to the calibration level until the comparator outputs the jump signal, wherein the steady-state signal is a signal whose amplitude remains unchanged within a preset time, and the jump signal is a signal whose amplitude changes between a high level and a low level within the preset time.

19. The electronic device according to claim 17, wherein the transmit circuit configures the DC common-mode level to a level to be measured that is the same as or different from the reference level;
wherein the first switch is turned on and the second switch is turned off to cause the first input terminal of the comparator to receive the level to be measured and to cause the second input terminal of the comparator to receive the reference level; and
wherein the comparator compares the level to be measured with the reference level to obtain a comparison result.

20. The electronic device according to claim 10, wherein a control terminal of the first switch and a control terminal of the second switch are configured to receive an enable signal,
wherein in response to the enable signal being at a first level, the first switch is turned off and the second switch is turned on; and
wherein in response to the enable signal being at a second level, the first switch is turned on and the second switch is turned off.
